(19) United States
(12) Patent Application Publication
(10) Pub. No.: US 2011/0310551 A1
(43) Pub. Date: Dec. 22, 2011

(54) DISK DRIVE WITH AUTOMATICALLY OPENING COVER

(75) Inventor: HE-LI WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/880,154

(22) Filed: Sep. 13, 2010

(30) Foreign Application Priority Data
Jun. 18, 2010 (CN) 201010202160.6

(51) Int. Cl. G06F 1/16; H05K 5/03

(52) U.S. Cl. 361/679.33

(57) ABSTRACT

A disk drive with automatically opening cover comprises a main body, a cover, a torsion spring, a buffering rod, and a buffering fork. Two connecting portions protrude from the cover, each passing through a corresponding through hole and a buffering rod protrudes from the vicinity thereof, perpendicular to the hinged edge and at a predetermined angle to the cover. The main body includes two buffering forks on a surface thereof facing away from the cover. Each of the buffering forks is located at an edge of the through hole apart from the hinged edge. The torsion spring is compressed between the main body and the cover such that, when released, the cover is driven thereby to pivotally open until the buffering rods are received by the corresponding buffering forks and movement thereof arrested.

### BACKGROUND

1. Technical Field

The present disclosure generally relates to disk drives, and particularly to a disk drive with automatically opening cover and a buffering element.

2. Description of the Related Art

Disk drives with automatically opening cover often include a main body, a cover hinging on the main body, and a plurality of torsion springs arranged between the cover and the main body. The cover hinges up from the main body by the torsion spring until stopped by the main body.

The impact of the cover and the main body can damage optical and electronic systems in the disk drive, shortening product life of the drive.

What is needed, therefore, is a disk drive with automatically opening cover which can avoid impact of the cover on the main body, and ameliorate the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the disk drive with automatically opening cover. Moreover, in the drawings, like reference numerals designate corresponding parts throughout the views.

FIG. 1 is a schematic view of a disk drive with automatically opening cover in an open state, in accordance with a first embodiment.

FIG. 2 is a schematic view of a disk drive with automatically opening cover in a closed state, in accordance with a first embodiment.

FIG. 3 is a partial exploded schematic view of a disk drive with automatically opening cover of FIG. 2.

FIG. 4 is a schematic view of a disk drive with automatically opening cover of FIG. 1 from another angle.

### DETAILED DESCRIPTION

Embodiments of a disk drive with automatically opening cover as disclosed are described in detail here with reference to the drawings.

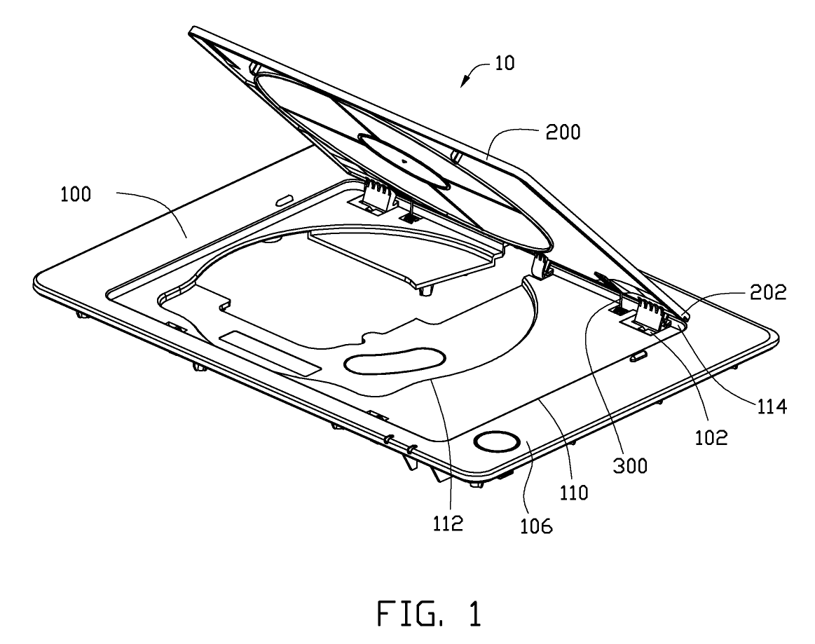

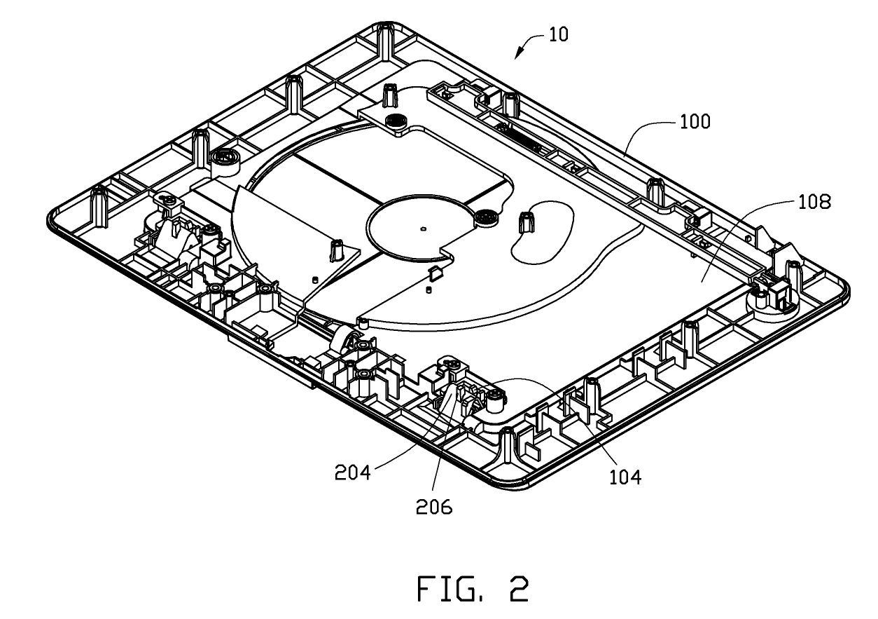

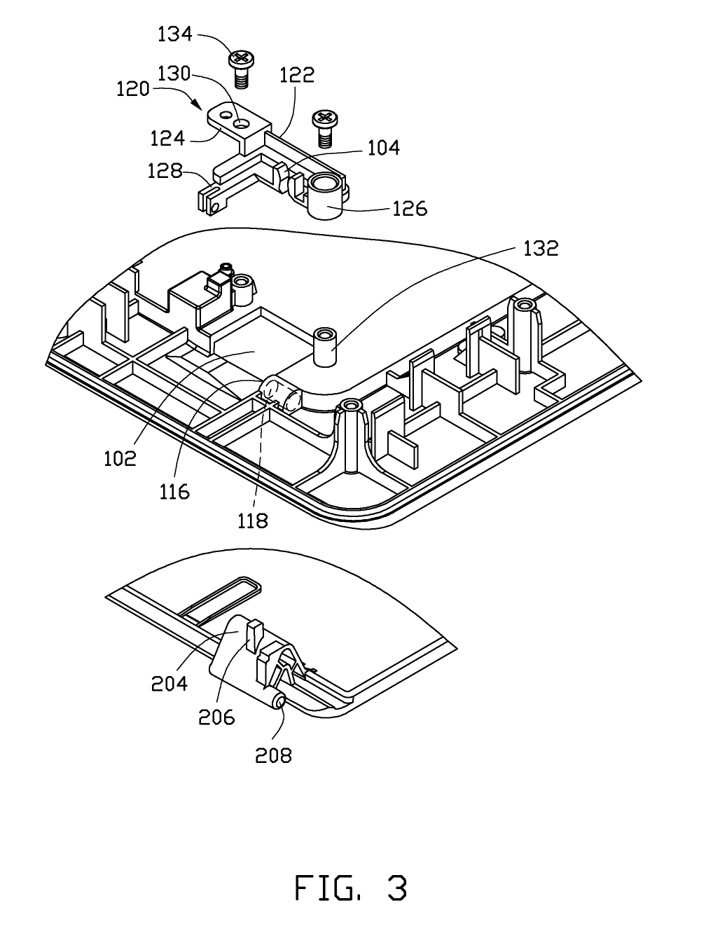

Referring to FIGS. 1-3, a disk drive with automatically opening cover 10 in accordance with a first embodiment includes a main body 100, a cover 200, and two torsion springs 300. The cover 200 includes a hinged edge 202 hinging on the main body 100. The main body 100 defines two through holes 102 near the hinged edge 202. Extending from the cover 200 are two connecting portions 204 (FIG. 2) corresponding to the through hole 102 from the hinged edge 202.

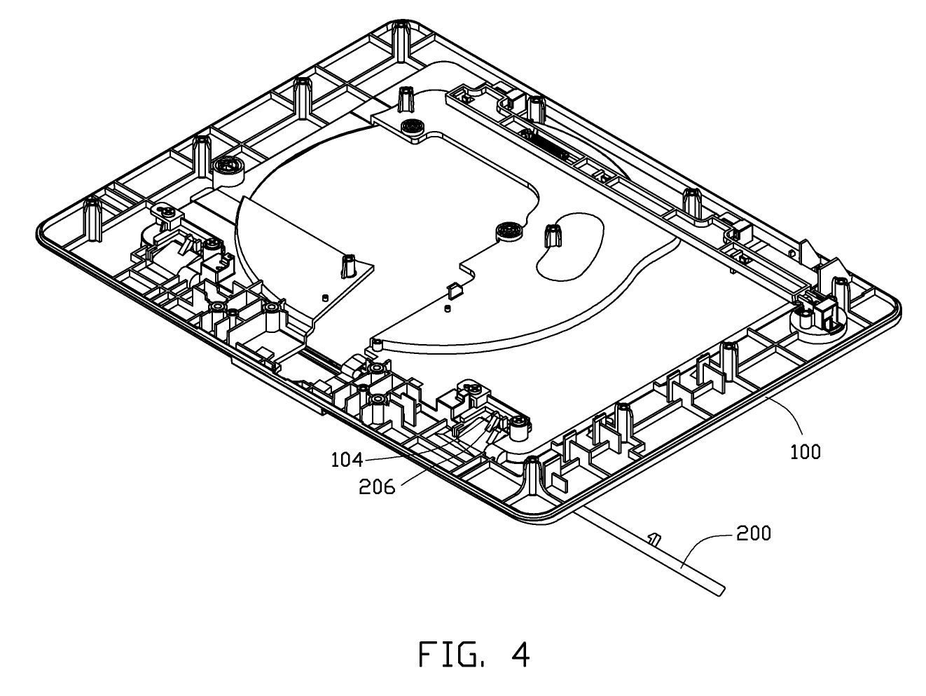

Each of the connecting portions 204 passes through a corresponding through hole 102 and a buffering rod 206 extends perpendicular to the hinged edge 202, forming a predetermined angle with the cover 200. Two buffering forks 104 corresponding to the two buffering rods 206 extend from the main body 100 on the side opposite to the cover 200. Each of the buffering forks 104 is away from the hinged edge 202 corresponding to a through hole 102. The two torsion springs 300 are arranged between the cover 200 and the main body 100 to swing the cover 200 away from the main body 100 around the hinged edge 202 until the two buffering rods 206 are separately received in the two corresponding buffering forks 104 serving as impact reduction (as shown in FIG. 4), protecting the disk drive from the impact of the cover on the main body.

In this embodiment, the main body 100 is substantially rectangular including a top surface 106 near the cover 200 and a bottom surface 108 opposite to the top surface 106. The main body 100 is configured with a rectangular recess 110 on the top surface 106, and a seating tray 112 is further configured inside the recess 110 for supporting a disk. The recess 110 further includes a connecting edge 114. The two through holes 102 are substantially rectangular and inside the recess 110 near the two ends of the connecting edge 114 passing through the top surface 106 and the bottom surface 108. Two pivotal seats 116 of the main body 100 are defined on the bottom surface 108 around a through hole 102 with a pivotal hole 118 thereon. The pivotal hole 118 faces a corresponding through hole 102 with longitudinal direction parallel to the hinged edge 202.

The cover 200 is substantially rectangular and essentially the same size or smaller than the recess 110. Pivotal shafts 208 extend from each of the connection portions 204 parallel to the hinged edge 202. The two connecting portions 204 are received in the through holes 102 from the top surface 106 and out to the bottom surface 108. Each of the pivotal shafts 208 is received in a corresponding pivotal hole 118 to hinge the cover 200 onto the main body 100.

The main body further includes two connecting plates 120, each comprising a transom 122, a wing blade 124 extending from one end of the transom 122 along the length thereof, a sleeve 126 at the other end of the transom 122, and a restriction beam 128 extending perpendicular to the transom 122 between the transom 122 and the wing blade 124, limiting a corresponding connecting portion 204 moving in a corresponding through hole 102.

Each of the wing blades 124 defines a threaded hole 130. The main body 100 defines two threaded sleeves 132 corresponding to the threaded hole 130. Each of the two threaded sleeves 132 is on each of the two sides of the through hole 102 away from the pivotal seat 116. Each of the connecting plates 120 is configured near a corresponding through hole 102 by two fasteners 134. Wherein the sleeve 126 is received in a corresponding threaded sleeve 132, the threaded hole 130 corresponds to a threaded sleeve 132, and the wing blade 124 and the sleeve 126 are fixed in the threaded sleeve 132 by two fasteners 134. The restriction beam 128 is at one side of the connecting portion 204 away from the pivotal shaft 208 cooperating with the transom 122 for restriction of connecting portion 204 inside the through hole 102 and maintaining the pivotal shaft 208 in the pivotal hole 118. There is no limitation of the manner of the pivoting mechanism.

The connecting plate 120 can be elastic material. In this embodiment, the buffering fork 104 is integrated with the connecting plate 120 and is elastic material for improved buffering effect. The buffering fork 104 extends from the middle of the transom 122.

The predetermined angle of the buffering rod 206 and the cover 200 is substantially the same that between the main body 100 and the cover 200 when the disk drive is opening. There is no limitation on the number of through holes 102, connecting portions 204, buffering rods 206, pivotal seats 116, and torsion springs 300.

It is to be understood, however, that even though numerous characteristics and advantages of the disclosure have been set forth in the foregoing description, together with details of the structures and functions of the embodiment(s), the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A disk drive with automatically opening cover comprising a main body, a cover, at least one torsion spring, at least one buffering rod, and at least one buffering fork, wherein the at least one torsion spring is arranged between the cover and the main body to swing the cover away from the main body until the at least one buffering rod is separately received in the corresponding at least one buffering fork, arresting movement of the cover.

2. The disk drive with automatically opening cover of claim 1, wherein the cover includes at least one hinged edge hinging on the main body, the main body defines at least one through hole near the hinged edge, at least one connecting portion extends from the cover corresponding to the at least one through hole from the hinged edge, each of the connecting portions passes through a corresponding through hole and the at least one buffering rod extends perpendicular to the hinged edge at a predetermined angle with the cover, the at least one buffering fork extends from the main body corresponding to the at least one buffering rod on the side opposite to the cover, and each buffering fork is away from the hinged edge corresponding to a through hole.

3. The disk drive with automatically opening cover of claim 2, wherein the main body includes a top surface near the cover and a bottom surface opposite to the top surface, the at least one through hole passing through the top surface and the bottom surface, wherein at least one pivotal seat is defined on the bottom surface around a through hole with a pivotal shaft parallel to the hinged edge and rotationally inserted into a corresponding pivotal seat.

4. The disk drive with automatically opening cover of claim 3, wherein each through hole is larger than each corresponding connecting portion.

5. The disk drive with automatically opening cover of claim 3, wherein the main body further includes at least one connecting plate comprising a transom, a wing blade extending from one end of the transom along a longitudinal axis, a sleeve at the other end of the transom, and a restriction beam extending perpendicular to the transom between the transom and the wing blade for restriction of a corresponding connecting portion in a corresponding through hole.

6. The disk drive with automatically opening cover of claim 5, wherein each buffering fork extends from the middle of a corresponding transom.

7. The disk drive with automatically opening cover of claim 6, wherein the connecting plate is elastic material.
